(19) United States
(12) Patent Application Publication
(10) Pub. No.: US 2007/0026666 A1
(43) Pub. Date: Feb. 1, 2007

(54) Method of forming metal line on semiconductor device

(75) Inventor: Jung Suk Won, Seoul (KR)

Correspondence Address: THE LAW OFFICES OF ANDREW D. FORTNEY, PH.D., P.C., 401 W FALLBROOK AVE STE 204, FRESNO, CA, 93711-5835, US

(73) Assignee: Dongbu Electronics, Co., Ltd.

(21) Appl. No.: 11/495,386

(22) Filed: Jul. 27, 2006

(30) Foreign Application Priority Data
Jul. 27, 2005 (KR) 10-2005-0068410

(51) Int. Cl. H01L 21/4763

(52) U.S. Cl. 438/624; 438/637; 438/675

(57) ABSTRACT

Provided is a method of forming a metal line of a semiconductor device. The method includes the following. A metal line is formed on a semiconductor substrate. An etch barrier layer is formed on the entire surface of the semiconductor substrate including the metal line. A low-k dielectric layer is formed on the etch barrier layer. The low-k dielectric layer is selectively removed to form a via hole using the etch barrier layer as an etch end point. Nitrogen gas is applied on the via hole to remove foreign substances formed during the forming of the via hole and simultaneously protect the side surface of the via hole.

### BACKGROUND OF THE INVENTION

1. Field of the Invention

The present invention relates to a metal line of a semiconductor device, and more particularly, to a method of forming a metal line of a semiconductor device to prevent an etch stop during etching of a low-k dielectric layer.

2. Description of the Related Art

Metals that are generally used to form metal lines of semiconductor devices include aluminum (Al), aluminum alloys, and tungsten (W).

However, because these metals have a low melting point and high specific resistance, their continued use in highly-integrated semiconductor devices manufactured today is problematic.

Accordingly, the need for a material for replacing materials for forming metal lines arises. Candidates having superior conductivity such as copper (Cu), gold (Au), silver (Ag), cobalt (Co), chrome (Cr), and nickel (Ni) have low selective resistance and superior reliability of their electro migration (EM) and stress migration (SM) characteristics. Copper and copper alloys that are inexpensive to use in manufacturing are widely used.

Copper metal lines according to the related art have lower specific resistance than aluminum to reduce their RC time delay, and are used in devices having a design rule of 0.13 μm or less.

Below, a metal line forming method in a semiconductor device according to the related art will be described in detail with reference to the diagrams.

FIGS. 1A through 1D are sectional views showing the forming of a metal line on a semiconductor substrate, according to the related art.

Referring to FIG. 1A, a conductive layer (of copper, for example) is formed on a semiconductor substrate 11, and the conductive layer is selectively patterned with photolithography and etching, to form a metal line 12.

Next, an etch barrier layer 13 (an SiC layer, for example) is formed over the entire surface of the semiconductor substrate 11 including the metal line 12.

Then, a low-k dielectric layer 14 (an SiCH layer, for example) is formed on the etch barrier layer 13, and a cap oxide layer 15 is formed on the low-k dielectric layer 14.

After a photoresist 16 is applied on the cap oxide layer 15, the photoresist 16 is selectively patterned by exposing and developing, forming a contact region.

Referring to FIG. 1B, the patterned photoresist 16 is used as a mask for selectively patterning the cap oxide layer 15.

Referring to FIG. 1C, the patterned photoresist 16 is also used as a mask for selectively patterning the low-k dielectric layer 14, forming a via hole 17.

Here, the forming of the via hole 17 is a process that connects one metal line to another. During an etching process of the via hole, a CₓF_{y} (C/F>0.5)-based gas that forms a large amount of polymer 18 is used as a main gas, and a gas such as Ar or O₂ is used as an adding gas to maximize the selectivity of the photoresist 16.

The above gas deposits a carbon-based polymer 18 on the bottom of the via hole 17 during the etching of the low-k dielectric layer, which prevents it from being etched further.

Referring to FIG. 1D, to overcome the polymer's 18 prevention of further etching, bias power is increased to increase ion energy and allow continued etching.

However, the critical dimension (CD) of the via hole 17 cannot be increased.

Also, while removal of the polymer 18 can be realized by increasing the amount of O₂ (for removing carbon-based polymers) used during the etching of the low-k dielectric layer 14, because the carbon content in the low-k dielectric layer 14 is also removed, its dielectric constant increases.

When the amount of O₂ used during the etching process of the low-k dielectric layer is increased in order to remove the carbon-based polymer, deterioration of the materials of the low-k dielectric layer occurs. That is, when the low-k dielectric layer is formed of an Si—O—CH substance, CH is added to SiO such that a permittivity thereof is lowered.

Additionally, when the supply of O₂ is increased to remove carbon-based polymers that were formed through a CH group during etching, it is effective for removing polymers, but causes an increase in the dielectric constant due to CH component being removed from the etched low-k dielectric layer.

That is, etching the low-k dielectric layer in a main etching process leads to polymers being deposited on the bottom of the via hole upon completion of the main etching. Then, the polymers cannot be removed in an over etch.

When O₂ is used to remove the polymers during the over etch, the carbon content of the low-k dielectric layer is somewhat depleted, causing an increase in its dielectric constant and a lowering of the selectivity between the SiC and SiOCH composing the etch barrier layer of the via hole. Thus, the metal line is open so that its reliability after being manufactured is compromised.

FIG. 2 is a sectional view of a metal line according to the related art.

Referring to FIG. 2, when a via hole 17 is formed, due to the polymer, the via hole 17 is not etched up to the etch barrier layer 13, so that further metal lines 19 that are formed cannot be electrically connected with existing metal lines 12.

### SUMMARY OF THE INVENTION

Accordingly, the present invention is directed to a method of forming a metal line of a semiconductor device that substantially obviates one or more problems due to limitations and disadvantages of the related art.

An object of the present invention is to provide a method of forming a metal line of a semiconductor device that prevents an increase in an etch stop and a dielectric constant during the forming of a via hole in a low-k dielectric layer, in order to increase the reliability of the metal line.

Additional advantages, objects, and features of the invention will be set forth in part in the description which follows and in part will become apparent to those having ordinary skill in the art upon examination of the following or may be learned from practice of the invention. The objectives and other advantages of the invention may be realized and attained by the structure particularly pointed out in the written description and claims hereof as well as the appended drawings.

To achieve these objects and other advantages and in accordance with the purpose of the invention, as embodied and broadly described herein, there is provided a method of forming a metal line of a semiconductor device, the method including: forming a metal line on a semiconductor substrate; forming an etch barrier layer on an entire surface of the semiconductor substrate including the metal line; forming a low-k dielectric layer on the etch barrier layer; selectively removing the low-k dielectric layer using the etch barrier layer for an etch end point to form a via hole; and applying a nitrogen gas on the via hole to remove foreign substances formed during the forming of the via hole, and simultaneously protecting a side surface of the via hole.

In another aspect of the present invention, there is provided a method of forming a metal line of a semiconductor device, including: forming a low-k dielectric layer on a semiconductor substrate; selectively etching the low-k dielectric layer to form a via hole, using a CₓF_{y}-based gas; and using nitrogen gas on the semiconductor substrate having the via hole formed thereon, for removing foreign substances formed on a bottom surface of the via hole during the forming of the via hole and simultaneously protecting a side surface of the via hole.

It is to be understood that both the foregoing general description and the following detailed description of the present invention are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this application, illustrate embodiment(s) of the invention and together with the description serve to explain the principle of the invention. In the drawings:

FIGS. 1A through 1D are sectional views showing the forming of a metal line on a semiconductor substrate, according to the related art;

FIG. 2 is a sectional view of a metal line according to the related art; and

FIGS. 3A through 3E are sectional views showing the forming of a metal line on a semiconductor substrate, according to the present invention.

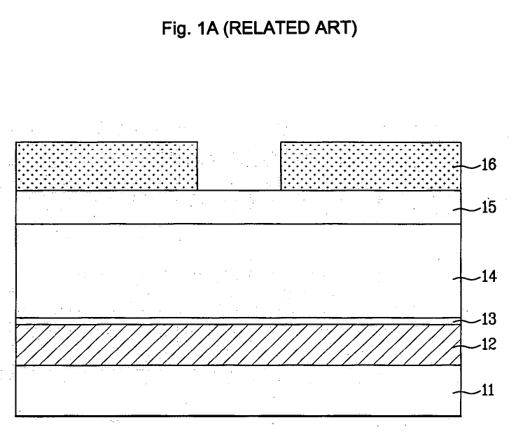

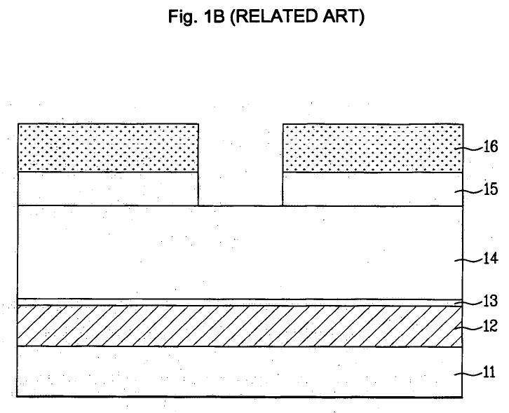

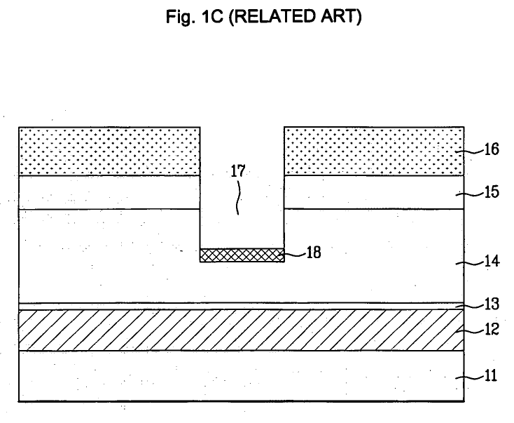

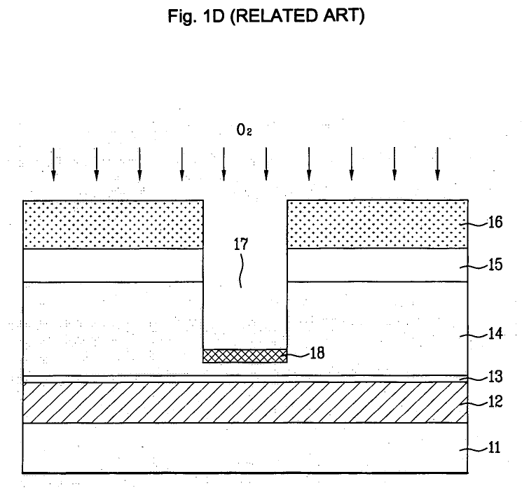

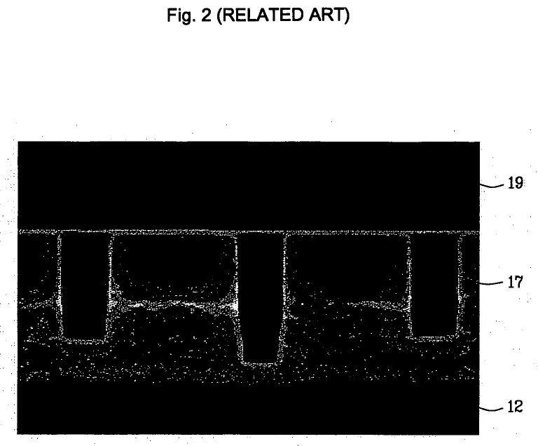

### DETAILED DESCRIPTION OF THE INVENTION

Reference will now be made in detail to the preferred embodiments of the present invention, examples of which are illustrated in the accompanying drawings. Wherever possible, the same reference numbers will be used throughout the drawings to refer to the same or like parts.

A detailed description for forming a metal line of semiconductor device will be given below, with reference to the diagrams.

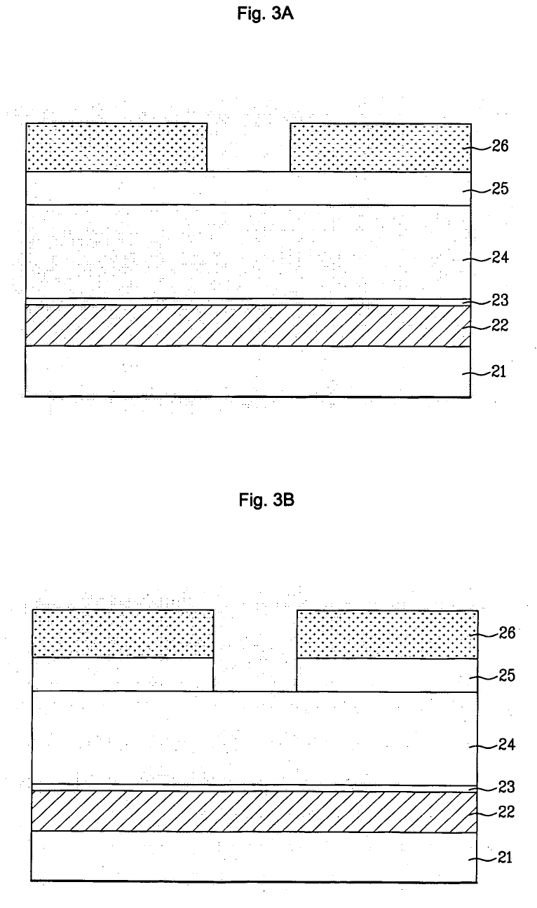

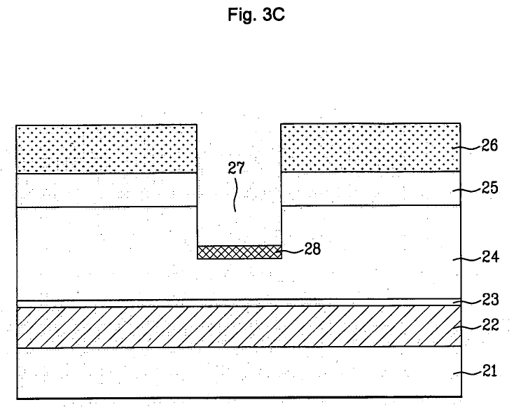

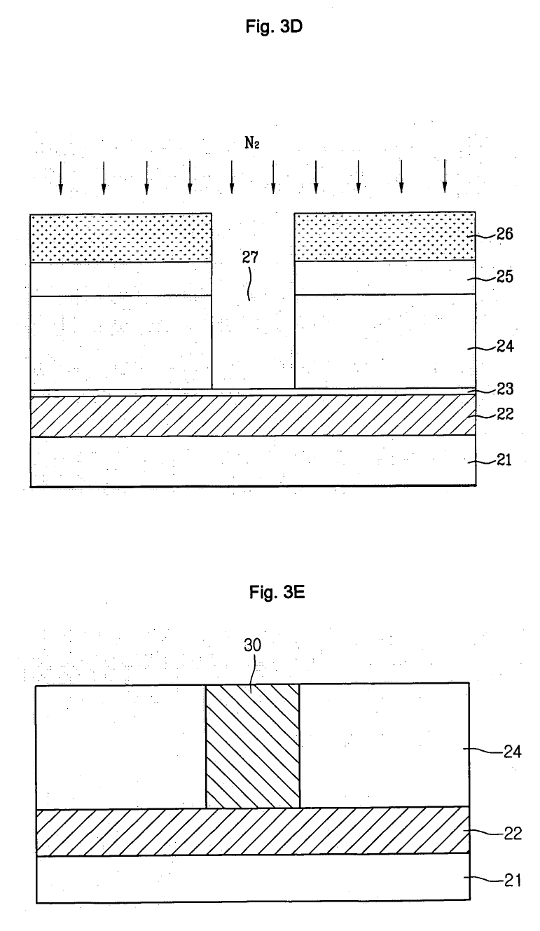

FIGS. 3A through 3E are sectional views showing the forming of a metal line on a semiconductor substrate, according to the present invention.

Referring to FIG. 3A, a conductive layer (of copper, for example) is formed on a semiconductor substrate 21, and the conductive layer is selectively patterned with photolithography and etching, to form a metal line 22.

Next, an etch barrier layer 23 (an SiC layer, for example) is formed over the entire surface of the semiconductor substrate 21 including the metal line 22.

Then, a low-k dielectric layer 24 (an SiCH layer, for example) is formed on the etch barrier layer 23, and a cap oxide layer 25 is formed on the low-k dielectric layer 24.

Here, an anti-reflective layer (not shown) may be formed on the cap oxide layer 25.

After a photoresist 26 is applied on the cap oxide layer 25, the photoresist 26 is selectively patterned by exposing and developing, forming a contact region.

Referring to FIG. 3B, the patterned photoresist 26 is used as a mask for selectively patterning the cap oxide layer 25.

Referring to FIG. 3C, the patterned photoresist 26 is also used as a mask for selectively patterning the low-k dielectric layer 24, forming a via hole 27.

Here, the forming of the via hole 27 is a process that connects one metal line to another. During an etching process of the via hole, a CₓF_{y} (C/F>0.5)-based gas that forms a large amount of polymer 28 is used as a main gas, and a gas such as Ar or O₂ is used as an adding gas to maximize the selectivity of the photoresist 26.

The above gas deposits a carbon-based polymer 28 on the bottom of the via hole 27 during the etching of the low-k dielectric layer 24, which prevents it from being etched further. In exemplary CₓF_{y}-based gases, 2≦x≦5, and y=2(x−n), where 1≦n≦(x−1), including C₂F₂, C₃F₄, C₄F₄, C₄F₆, C₅F₆, and C₅F₈ (the last 3 of which may be cyclic, linear or branched). However, it is also contemplated that fluorocarbons in which C/F=0.5 (where 2≦x≦5) may also be useful, such as C₂F₄, C₃F₆, C₄F₈, and C₅C₁₀ (the last 3 of which may be cyclic, linear or branched).

Referring to FIG. 3D, nitrogen (N₂) gas is used on the entire surface of the semiconductor substrate 21 to remove the polymer 28 created during the forming of the via hole 27.

Next, the photoresist 26 is used as a mask and bias power and ion energy are increased to perform an over etch for exposing the surface of the etch barrier layer 23.

According to the present invention, the N₂ gas used to remove the polymer 28 during the forming of the via hole 27 protects the side surfaces of the via hole 27 during the over etch, so that removal of carbon from the low-k dielectric layer 24 is prevented, and at the same time, the carbon-based polymer 28 deposited at the bottom of the via hole 27 is removed as CN.

The nitrogen gas has a pressure of 280 mT, an ion energy of 400W, a bias voltage of 100W, and a nitrogen content of 600 sccm. Here, 500 sccm of H₂ and/or 15 sccm of CF₄ may be added and used. The processing time is approx. 10-30 seconds.

Then, the photoresist 26 and cap oxide layer 25 are removed, and a diffusion barrier layer and a copper or similar layer are deposited on the inside of the via hole 27. Next, chemical mechanical polishing (CMP) is performed, and other metal lines to be connected to the metal line 22 are formed.

It will be apparent to those skilled in the art that various modifications and variations can be made in the present invention.

Thus, it is intended that the present invention covers the modifications and variations of this invention provided they come within the scope of the appended claims and their equivalents.

The above-described metal line forming method of a semiconductor according to the present invention has the following effects.

When a low-k dielectric layer is etched to form a via hole, nitrogen gas is used to remove polymer formed during the via hole forming process and to simultaneously protect the side surfaces of the via hole to prevent non-uniformity of the via hole's critical dimension during an over etch.

Accordingly, an RC time delay can be improved by reducing a via hole fail probability and preventing a decrease of carbon in the low-k dielectric layer in a semiconductor device with a low-k dielectric layer.

What is claimed is:

1. A method of forming a contact hole in a semiconductor device, the method comprising:
forming a metal line on a semiconductor substrate;
forming an etch barrier layer on an entire surface of the semiconductor substrate including the metal line;
forming a low-k dielectric layer on the etch barrier layer;
selectively removing the low-k dielectric layer using the etch barrier layer as an etch end point to form a via hole; and
applying a nitrogen gas on the via hole to remove foreign substances from inside the via hole, and simultaneously protecting a side surface of the via hole.

2. The method according to claim 1, wherein the low-k dielectric layer comprises SiOCH.

3. The method according to claim 1, wherein selectively removing the low-k dielectric layer comprises etching the low-k dielectric layer with a CₓF_{y}-based gas.

4. The method according to claim 3, wherein the low-k dielectric layer is etched with a mixture of the CₓF_{y}-based gas and an oxygen source or argon gas.

5. The method according to claim 1, wherein the etch barrier layer comprises SiC.

6. The method according to claim 1, wherein the foreign substances comprise a carbon-based polymer.

7. The method according to claim 6, wherein removing the carbon-based polymer comprises forming a volatile CN-based material with the nitrogen gas.

8. The method according to claim 1, further comprising, after forming the via hole, forming a metal layer on the entire surface of the semiconductor substrate filling an inside of the via hole, and performing a CMP (chemical mechanical polishing) process.

9. The method according to claim 1, wherein applying the nitrogen gas comprises the following conditions: 280 mT of pressure, 400W of ion energy, 100W of bias voltage, and 600 sccm of nitrogen.

10. The method according to claim 1, wherein the nitrogen gas has H₂ gas and/or CF₄ gas added thereto.

11. A method of forming a metal line of a semiconductor device, comprising:
forming a low-k dielectric layer on a semiconductor substrate;
selectively etching the low-k dielectric layer to form a via hole, using a CₓF_{y}-based gas; and
using nitrogen gas on the semiconductor substrate and the via hole to remove foreign substances on a bottom surface of the via hole and simultaneously protect a side surface of the via hole.

12. The method according to claim 11, wherein the low-k dielectric layer comprises SiOCH.

13. The method according to claim 11, wherein the low-k dielectric layer is selectively etched with a mixture in which the CₓF_{y}-based gas is a main gas.

14. The method according to claim 11, wherein the low-k dielectric layer is etched with a mixture comprising oxygen or argon gas and the CₓF_{y}-based gas.

15. The method according to claim 11, wherein the etch barrier layer comprises SiC.

16. The method according to claim 11, wherein the foreign substances comprise a carbon-based polymer.

17. The method according to claim 16, wherein using the nitrogen gas comprises forming a CN-based material from the carbon-based polymer and the nitrogen gas.

18. The method according to claim 11, further comprising, after the forming of the via hole, forming a metal layer on an entire surface of the semiconductor substrate, filling an inside of the via hole, and performing a CMP (chemical mechanical polishing) process.

19. The method according to claim 11, wherein using the nitrogen gas comprises forming a plasma under the following conditions: 280 mT of pressure, 400W of ion energy, 100W of bias voltage, and 600 sccm of nitrogen.

20. The method according to claim 11, wherein the nitrogen gas has H₂ gas and/or CF₄ gas added thereto.
